(19) United States
(12) Patent Application Publication
(10) Pub. No.: US 2026/0162746 A1
(43) Pub. Date: Jun. 11, 2026

(54) CROSS-MEMORY RANK ERROR MANAGEMENT

(71) Applicant: Micron Technology, Inc., Boise, ID (US)

(72) Inventors: Nicola Del Gatto, Cassina de' Pecchi (IT); Nicola Corna, Gorle (BG) (IT); Marco Sforzin, Cernusco Sul Naviglio (MI) (IT)

(21) Appl. No.: 19/391,787

(22) Filed: Nov. 17, 2025

Related U.S. Application Data
(60) Provisional application No. 63/729,837, filed on Dec. 9, 2024.

(51) Int. Cl. G11C 29/38

(52) U.S. Cl. CPC G11C 29/38

(57) ABSTRACT

A memory system may be configured to store a codeword at least partially in a first memory rank and at least partially in a second memory rank, where a data portion of the codeword may be at least partially stored in the first memory rank and an error management portion of the codeword may be at least partially stored in the second memory rank. After storing the codeword in the first memory rank and the second memory rank, the codeword may be retrieved from the first memory rank and the second memory rank. And based on retrieving the codeword, one or more errors in the data portion of the codeword retrieved from the first memory rank may be corrected using the error management portion of the codeword retrieved from the second memory rank.

### CROSS REFERENCE

The present Application for Patent claims priority to U.S. Patent Application No. 63/729,837 by Gatto et al., entitled “CROSS-MEMORY RANK ERROR MANAGEMENT,” filed Dec. 9, 2024, which is assigned to the assignee hereof, and which is expressly incorporated by reference in its entirety herein.

### TECHNICAL FIELD

The following relates to one or more systems for memory, including cross-memory rank error management.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports cross-memory rank error management in accordance with examples as disclosed herein.

FIG. 2 shows an example of a subsystem that supports cross-memory rank error management in accordance with examples as disclosed herein.

FIG. 3 shows an example of a subsystem that supports cross-memory rank error management in accordance with examples as disclosed herein.

FIG. 4 shows an example of a subsystem that supports cross-memory rank error management in accordance with examples as disclosed herein.

FIG. 5 shows an example of a subsystem that supports cross-memory rank error management in accordance with examples as disclosed herein.

FIG. 6 shows an example of a set of operations for cross-memory rank error management in accordance with examples as disclosed herein.

FIG. 7 shows a block diagram of a memory system that supports cross-memory rank error management in accordance with examples as disclosed herein.

FIGS. 8 and 9 show flowcharts illustrating a method or methods that support cross-memory rank error management in accordance with examples as disclosed herein.

### DETAILED DESCRIPTION

Certain computing systems (e.g., data centers) may have stringent data failure requirements (e.g., a low annualized failure rate threshold, a low silent data corruption threshold, etc.) for which single die data correction capabilities may be insufficient. One option to meet these stringent data failure requirements is to limit a memory system to high quality memory dies (e.g., memory dies that are graded above a threshold level and less likely to fail). However, doing so may significantly increase a cost of the memory system. Another option is to implement a Reed-Solomon code that provides a higher level of memory die failure correction (e.g., double die data correction) within a group of memory cells. However, doing so may introduce excessive overprovisioning overhead and may reduce an amount of memory available at the data center. Thus, implementations that support increasing a data protection capability of a memory system without increasing (or with a reduced increase in) overprovisioning overhead may be desired.

To increase a data protection capability of a memory system without increasing (or with a reduced increase in) overprovisioning overhead, a codeword (e.g., a Reed Solomon codeword) storing error management information may be stored across multiple groups of memory cells (e.g., across multiple ranks, which may be associated with one or more channels).

In addition to applicability in memory systems as described herein, techniques for cross-memory rank error management may be generally implemented to support cloud computing and storage applications, among other potential applications. As the use of cloud computing to provide processing, storage, and networking services to multiple devices increases, many devices and systems may benefit from improved remote processing and storage capabilities. For example, increasing memory capacity or other capabilities may result in larger and more accessible storage options for users, and increasing memory access times may result in faster processing for computing or database applications. Implementing the techniques described herein may support cloud computing and storages techniques by increasing a reliability of memory within a cloud environment (by enabling dual-die error correction), which may enable lower cost memory to be used by the cloud environment, with reduced (or no) increase in overprovisioning overhead, which may enable higher reliability characteristics to be achieved without reducing (or a smaller reduction) in the memory available at the cloud environment, among other benefits.

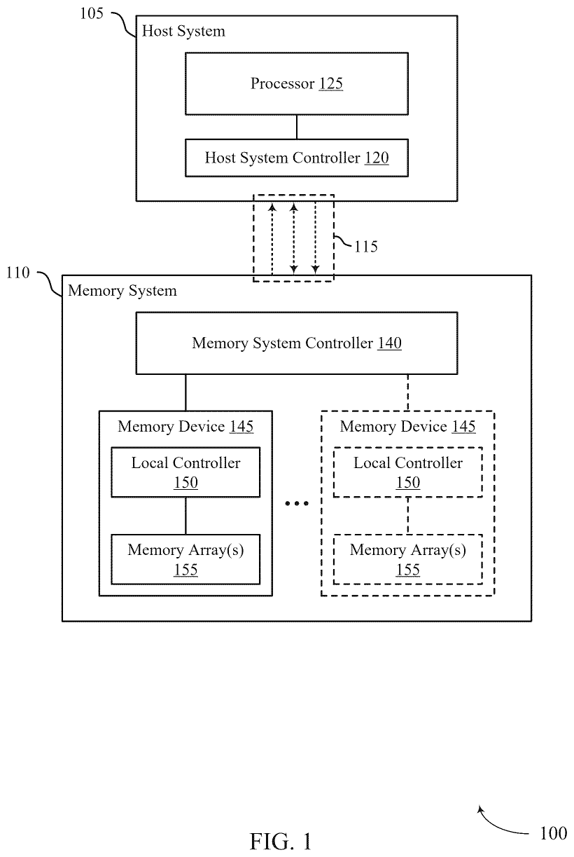

FIG. 1 shows an example of a system 100 that supports cross-memory rank error management in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105 and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A memory system may include multiple memory dies (e.g., 10, 20, 30, 40, 50, 60, 70, 80, etc.). The memory dies may be organized into one or more groups (which may be referred to as “ranks” or “memory ranks”). The memory dies within a memory rank may be simultaneously accessed with a corresponding chip select signal. Memory dies in different ranks may be separately accessed with separate chip select signals. Accordingly, the memory dies in a memory rank may enable blocks of data to extend across memory dies. A memory system that includes multiple ranks may support lower-latency data access (e.g., by allowing multiple DRAM pages to remain open, which may increase the probability of getting a “hit” on an already open row address).

The memory system may also include a bus (e.g., a 40-bit bus) over which data can be transmitted from or to the memory dies. In some examples, a subset of the memory dies (or groups of memory dies) may be associated with a first channel of the memory system and a second subset of the memory dies (or groups of memory dies) may be associated with a second channel of the memory system. In some examples, the memory system may include multiple buses—e.g., if the memory system supports multiple channels.

A memory system may support reading from the memory system (e.g., from a memory rank in the memory system) using one or more burst lengths (e.g., a 16-beat burst length, or an 8-beat burst length). In some examples, a first burst length (e.g., BL16) may enable full channel utilization throughout the burst (e.g., data may be communicated on each beat). In some examples, a second burst length (e.g., BC8) may not fully utilize a channel throughout the burst (e.g., the second burst length may achieve 50% utilization of the channel). For example, a second burst length may utilize the first eight beats, observe a bubble during the next eight beats in which no data is communicated from the memory system, utilize the next eight beats, and observe a second bubble during the next eight beats. In some examples, the first burst length supports reading a full set of data stored in a page of the memory system while the second burst length may support reading a subset (e.g., half) of the data stored in a page of the memory system. In some examples, reading a subset of the data stored in a page of the memory system is more efficient for certain operations (e.g., for operations that use a portion of the data stored in the page, for operations that involve a high processing load, etc.).

Reed-Solomon codes can be used to recover the loss of one or more data symbols (e.g., 8-bit data symbols) stored in a memory system. In some examples, the quantity of data symbols that can be recovered using a Reed-Solomon code is based on the data symbol length, SymbLen (in bits), the parity symbol length SymbLen (in bits), a quantity of data symbols, CW_{SymbData}, in a Reed-Solomon codeword (which may be referred to as a “codeword”), and a quantity of total symbols (e.g., data and parity symbols), CW_{symbTtl}, in the codeword. For example, the error correction capability of a particular Reed-Solomon code, which may be represented as RS (2^{SymbLen}, CW_{symbTtl}, CW_{SymbData}), may be computed as follows:

$$\frac{( {CW}_{SymbTtl} - {CW}_{SymbData} )}{2} ,$$

where CW_{SymbTtl}=CW_{bitsTtl}/SymbLen.

For instance, for a Reed-Solomon code having the following values RS (28, 40, 32), the error correcting capability of the Reed-Solomon code may be up to four (4) data symbols, (320/8−32)÷2.

As described above, a memory system may include groups of memory dies (e.g., groups of ten memory dies, including eight data dies and two parity dies) within a memory rank. In some examples, a Reed-Solomon code may be capable of accommodating the failure of a full memory die (which may be referred to as a “single die data correction” capability) within a memory rank—e.g., using the uncorrupted data symbols of the remaining memory dies and the parity symbols of the parity dies. For example, for a codeword stored across the ten memory dies (including eight data dies and two parity dies) and having a symbol length of eight bits, the Reed-Solomon code may be capable of recovering all the data stored in the codeword even if four symbols of a communicated codeword (stored across multiple memory dies or in a single memory die) are corrupted—e.g., due to a memory die failure.

Though Reed-Solomon codes provide error management capabilities (including error detection and correction), the usage of Reed-Solomon codes introduces overprovisioning overhead into the memory system. For example, a Reed-Solomon code that can recover the loss of an entire memory die may introduce

$$25 \% ( \frac{2 parity dies}{8 data dies} )$$

overprovisioning overhead into the memory system. Also, a Reed-Solomon code that can recover the loss of two entire memory dies within a group of memory dies may introduce

$$50 \% ( \frac{4 parity dies}{8 data dies} )$$

overprovisioning overhead into the memory system.

Certain computing systems (e.g., data centers) may have stringent data failure requirements (e.g., a low annualized failure rate threshold, a low silent data corruption threshold, etc.) for which single die data correction capabilities may be insufficient. One option to meet these stringent data failure requirements is to limit a memory system to high quality memory dies (e.g., memory dies that are graded above a threshold level and less likely to fail). However, doing so may significantly increase a cost of the memory system. Another option is to implement a Reed-Solomon code that provides a higher level of memory die failure correction (e.g., double die data correction) within a group of memory cells. However, doing so may introduce excessive overprovisioning overhead and may reduce an amount of memory available at the data center.

Thus, implementations (e.g., methods, systems, apparatuses, techniques, configurations, components) that support increasing a data protection capability of a memory system without increasing (or with a reduced increase in) overprovisioning overhead may be desired.

To increase a data protection capability of a memory system without increasing (or with a reduced increase in) overprovisioning overhead, a codeword (e.g., a Reed Solomon codeword) storing error management information may be stored across multiple groups of memory cells (e.g., across multiple ranks, which may be associated with one or more channels).

In some examples, a memory system (e.g., the memory system 110) that includes a first memory rank and a second memory rank (which may be coupled with a same or different channels) may be configured to store a codeword in the first memory rank and the second memory rank (e.g., in memory dies of the first memory rank and in memory dies of the second memory rank), which may be associated with an address. In some examples, a first data portion of the codeword is stored in the first memory rank and a first error management portion of the codeword is stored in the second memory rank. Also, a second data portion of the codeword may be stored in the second memory rank and a second error correction portion of the codeword may be stored in the first memory rank. After storing the codeword, the memory system may retrieve the codeword from the first memory rank and the second memory rank (e.g., from the address)—e.g., may retrieve the first data portion from memory cells in the first memory rank and the first error correction portion from memory cells in the second memory rank as well as the second data portion from memory cells in the second memory rank and the second error correction portion from memory cells in the first memory rank.

Based on retrieving the codeword from the first memory rank and the second memory rank, the memory system may detect whether there are any errors in the codeword—e.g., using error correction data (e.g., a Reed-Solomon code, a cyclic redundancy check code) included in the first error correction portion of the codeword stored in the second memory rank, the second error correction portion of the codeword stored in the first memory rank, or both. In some examples, the memory system may detect and correct one or more errors (e.g., one or more symbol errors) in the first data portion of the codeword stored in the first memory rank using the first error management portion stored in the second memory rank, the second error management portion stored in the first memory rank, or both. In some cases, the memory system may detect and correct multiple errors (e.g., eight symbol errors, which may correspond to the failure of two memory dies) in the first data portion of the codeword stored in the first memory rank using the first error management portion stored in the second memory rank and the second error management portion stored in the first memory rank.

By storing the data portion and error management portion of a codeword across multiple memory ranks (e.g., coupled with a same or different channels), the error correcting capabilities of the memory system within a memory rank may be doubled without increasing overprovisioning overhead for the memory system. Thus, lower grade memory devices (e.g., that are more susceptible to failures) may provide higher reliability performance, which may allow lower grade memory devices to be used in application with stringent data failure requirements.

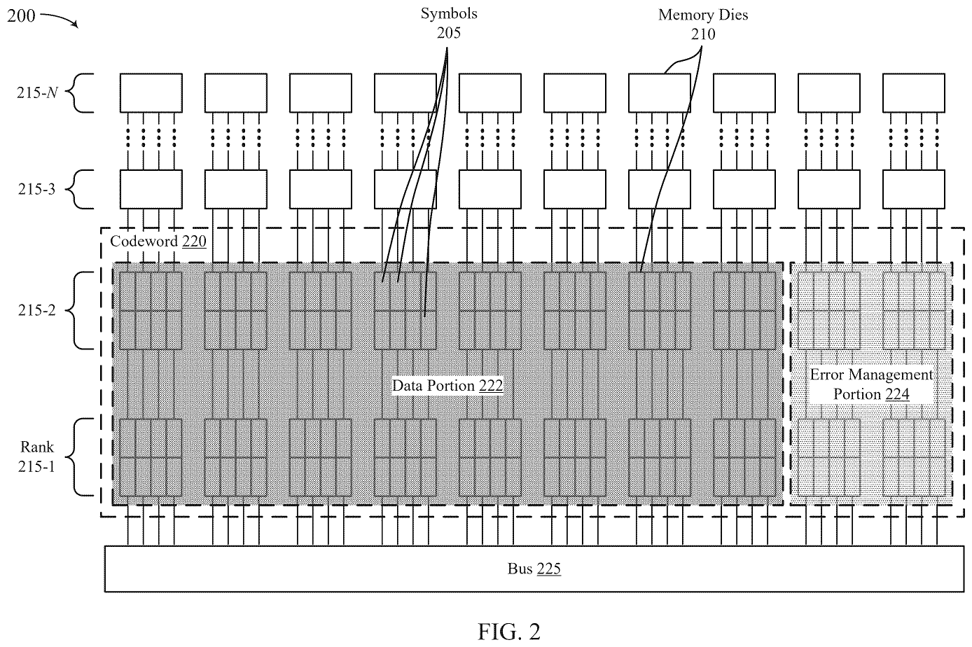

FIG. 2 shows an example of a subsystem that supports cross-memory rank error management in accordance with examples as disclosed herein.

The subsystem 200 may include the memory dies 210 and the bus 225. Each of the memory dies 210 may have four (4) connections to the bus 225—e.g., for a total of forty (40) connections.

Groups of the memory dies 210 may be organized into memory ranks 215 (e.g., memory ranks 215-1, 215-2, 215-3, through 215-N). In some examples, the memory dies 210 are grouped into groups of ten (10) memory dies. For example, the first memory rank 215-1 may include a first group of the memory dies 210, the second memory rank 215-2 may include a second group of the memory dies 210, the third memory rank 215-3 may include a third group of the memory dies 210, and so on. In some examples, the group of memory dies within a first memory rank may be simultaneously accessed using a first chip select signal and a first set of control signals, the group of memory dies within a second memory rank may be simultaneously accessed using a second chip select signal and a second set of control signals, and so on. Further, a first group of memory dies within a first memory rank may be separately accessed from a second group of memory dies within a second memory rank. Accordingly, an address within a first memory rank may remain open while an address within a second memory rank is being accessed, and vice versa.

In some examples, data may be stored in a memory die as symbols (e.g., the symbols 205)—for example, when a Reed-Solomon error management technique is used. The symbols may be four-bit symbols, eight-bit symbols, sixteen-bit symbols, etc. In some examples, a page of a memory system may be comprised of eighty (80) symbols (e.g., for a 640-bit page (including 512 user data bits and 128 error management bits) if eight-bit symbols are used) spanning a group of memory dies.

The bus may be configured to communicate signals between the memory dies 210 and a controller (e.g., at a memory system, a host system, or both). As noted above, each memory rank may include ten (10) memory dies, and the bus 225 may include forty (40) connections to the memory dies. As such, forty (40) bits may be communicated via the bus 225 with a memory rank at a time. In some examples, the data stored in a page of memory may be communicated in sixteen (16) forty-bit increments, where a first bit of a first set of symbols stored across a memory rank is output during a first clock cycle, a second bit of the first set of symbols stored across the memory rank is output during a second clock cycle, and so on. Further, a first bit of a second set of symbols stored across the memory rank is output during a next clock cycle, a second bit of the second set of symbols stored across the memory rank is output during a following clock cycle, and so on—e.g., until sixteen (16) sets of forty (40) bits have been communicated via the bus 225.

In some examples, data may be communicated via the bus 225 between the memory dies and a controller in bursts. For example, the data in a page of a memory system may be output as a burst of forty-bit signals (which may include one bit from each symbol in a set of symbols stored across a memory rank) that are communicated over consecutive “beats” of a clock. For example, if a burst length of sixteen (16) (which may also be referred to as burst length 16, BL16) is used, sixteen (16) forty-bit signals may be communicated over sixteen (16) beats to communicate 640 bits of data, which may correspond to the data stored in a page associated with a memory rank. In another example, if a burst length of eight (8) (which may also be referred to as a burst chop 8, BC8) is used, eight (8) forty-bit signals may be communicated over eight (8) beats to communicate 320-bits of data, which may correspond to half of the data (or half of the symbols) stored in a page associated with a memory rank. In some examples, to maintain common timing for different burst lengths, smaller burst lengths may include inactivity periods (which may be referred to as “bubbles”) during which data is not transmitted.

In some examples (e.g., when a Reed-Solomon error management technique is used), sets of data (e.g., a page of data, half a page of data, etc.) may be stored in the memory system as codewords, which may include data portions (which may also be referred to as “user data” portions) and error management portions. For example, a codeword may be stored across a memory rank such that a first data portion of the codeword may be stored across a first set of (e.g., eight) memory dies in the memory rank and a second error management portion of the codeword 220 may be stored across a second set of (e.g., two) memory dies in the memory rank.

For illustrative clarity, the codewords 220 in FIG. 2 is illustrated as surrounding multiple memory dies 210 in their entirety. It is to be understood, however, that in practice, in at least some examples, for codeword as described herein (e.g., a codeword 220, 320, 420, or 520) that spans (e.g., is stored across) multiple memory dies 210, a respective portion of the codeword 220 may be stored in a corresponding respective portion of each memory die 210 spanned by the codeword. That is, the respective portion of the codeword 220 that is stored within a particular memory die 210 need not occupy the entirety of that memory die 210 but instead may occupy only a respective portion of the memory die 210 (e.g., a codeword 220 may correspond to a page within the memory system, with the page being stored using a respective portion of each memory die 210 included in the set of memory dies 210 spanned by the codeword). Thus, multiple codewords 220 may span the same set of memory dies 210, with different portions of each of the memory dies 210 allocated to respective portions of the different codewords 220.

As described herein, to increase an error correcting capability of an error correction technique (e.g., a Reed-Solomon technique) within a memory rank without increasing an overprovisioning overhead in a memory system, a codeword (e.g., the codeword 220) may be stored across multiple memory ranks (e.g., the first memory rank 215-1 and the second memory rank 215-2). For example, a data portion 222 of the codeword 220 may be stored across a first set of memory dies in the first memory rank 215-1 and a first set of memory dies in the second memory rank 215-2. Also, an error management portion 224 of the codeword 220 may be stored across a second set of memory dies in the first memory rank 215-1 and a second set of memory dies in the second memory rank 215-2.

As such, error management information in the error management portion 224 may be used to correct symbols errors in the codeword 220 that occur in a part of the data portion 222 that is located within the first memory rank 215-1, in a part of the data portion 222 that is located within the second memory rank 215-2, or both. For example, for a Reed-Solomon code having the following values RS (28, 160, 128), the error management information may be used to correct up to sixteen (16) data symbols, (1280/8−128)÷2, that occur in the first memory rank 215-1, the second memory rank 215-2, or both. Accordingly, the error management information may be used to correct a failure of two memory dies within a single memory rank (e.g., the first memory rank 215-1, or the second memory rank 215-2).

In some examples, the codeword may be communicated with the memory system in two (e.g., consecutive) BL16 commands, where the first BL16 command may access the data stored in a page of the first memory rank 215-1 and the second BL16 command may access the data stored in a page of the second memory rank 215-2.

In some examples, the error management portion 224 may support multiple types of error management information (e.g., a Reed-Solomon code, a cyclic redundancy check code, etc.), multiple types of management information (e.g., metadata), or both.

In some examples, the error management portion 224 may include a Reed-Solomon code and metadata. In such cases, the error correcting capability of the Reed-Solomon code may be reduced relative to allocating the full error management portion 224 to the Reed-Solomon code. For example, if sixteen (16) symbols are allocated to a Reed-Solomon code and sixteen (16) symbols are allocated to metadata, the error management portion 224 may support the correction of up to eight (8) symbol failures (or a single die failure), (160−(128+16))÷2, and the communication of sixteen (16) bytes of metadata. In another example, if twenty (20) symbols are allocated to a Reed-Solomon code and twelve (12) symbols are allocated to metadata, the error management portion 224 may support the correction of up to ten (10) symbol failures (or a die-and-a-quarter failure), (160−(128+12))÷2, and the communication of twelve (12) bytes of metadata. In some examples, the metadata may instead be user data, which may increase an available storage capacity of the subsystem 200 to a user.

In some examples, the error management portion 224 may include a Reed-Solomon code and a cyclic redundancy check code computed for the data portion 222. For example, sixteen (16) symbols may be allocated to a Reed-Solomon code and sixteen (16) symbols may be allocated to a cyclic redundancy check code.

In some examples, the error management portion 224 may include a Reed-Solomon code, metadata, and a cyclic redundancy check code computed for the data portion 222. For example, sixteen (16) symbols may be allocated to a Reed-Solomon code, eight (8) symbols may be allocated to metadata, and eight (8) symbols may be allocated to a cyclic redundancy check code. In another example, twenty (20) symbols may be allocated to a Reed-Solomon code, six (6) symbols may be allocated to metadata, and six (6) symbols may be allocated to a cyclic redundancy check code.

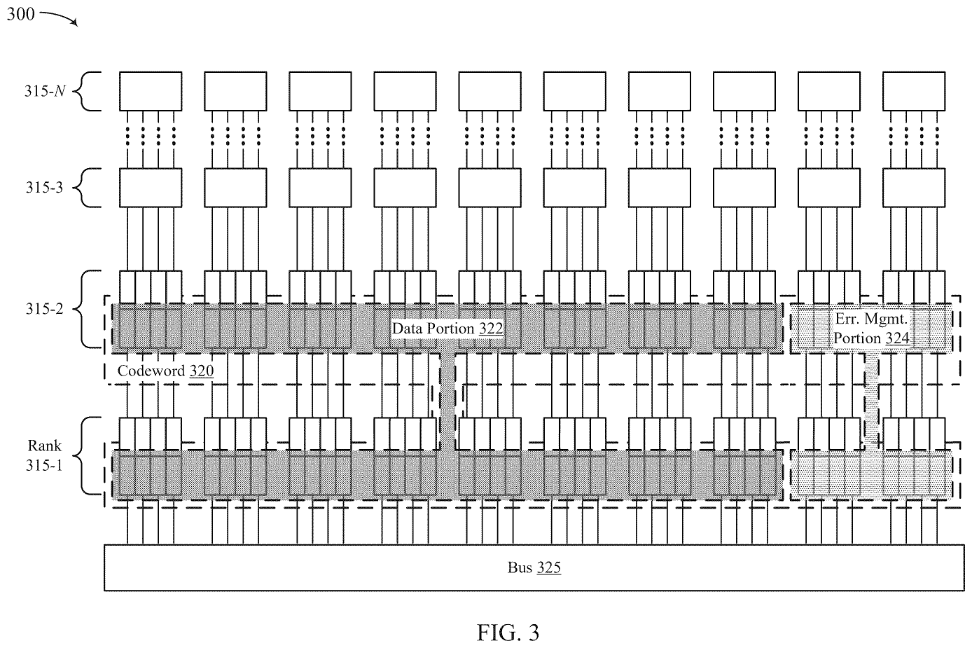

FIG. 3 shows an example of a subsystem that supports cross-memory rank error management in accordance with examples as disclosed herein.

The subsystem 300 may include the memory dies (which may be the same as or similar to the memory dies 200 of FIG. 2) and the bus 325, which may, respectively, be examples of, or configured similarly as, memory dies and buses described herein, including with reference to FIG. 2.

As described herein, to increase an error correcting capability of an error correction technique (e.g., a Reed-Solomon technique) within a memory rank (e.g., the memory ranks 315-1, 315-2, 315-3, through 315-N) without increasing an overprovisioning overhead in a memory system, a codeword (e.g., the codeword 320) may be stored across multiple ranks (e.g., the first memory rank 315-1 and the second memory rank 315-2). For example, a data portion 322 of the codeword 320 may be stored across a first set of memory dies in the first memory rank 315-1 and a first set of memory dies in the second memory rank 315-2. Also, an error management portion 324 of the codeword 320 may be stored across a second set of memory dies in the first memory rank 315-1 and a second set of memory dies in the second memory rank 315-2.

In some examples, a first part of the data portion 322 is stored in a portion of a page of the first memory rank 315-1 and a second part of the data portion 322 is stored in a portion of a page of the second memory rank 315-2. Similarly, a first part of the error management portion 324 may be stored in the portion of the page of the first memory rank 315-1 and a second part of the error management portion 324 may be stored in a portion of a page of the second memory rank 315-2.

As such, error management information in the error management portion 324 may be used to correct symbols errors in the codeword 320 that occur in a part of the data portion 322 that is located within the first memory rank 315-1, in a part of the data portion 322 that is located within the second memory rank 315-2, or both. For example, for a Reed-Solomon code having the following values RS (28, 80, 64), the error management information may be used to correct up to eight (8) data symbols, (640/8−64)÷2, that occur in the first memory rank 315-1, the second memory rank 315-2, or both. Accordingly, the error management information may be used to correct a failure of two memory dies within a single memory rank (e.g., the first memory rank 315-1, or the second memory rank 315-2).

In some examples, the codeword 320 may be communicated with the memory system in two (e.g., consecutive) BC8 commands, where the first BC8 command may access the data stored in a portion of a page in the first memory rank 315-1 and the second BC8 command may access the data stored in a portion of a page in the second memory rank 315-2. Accessing smaller codewords (e.g., relative to a codeword that spans two full ranks) may simplify complexity associated with processing codewords (e.g., at an ASIC level) and may reduce the bandwidth associated with processing codewords that are stored across ranks. In some examples, BL8 commands may be used in addition to or instead of BC8 commands.

As described herein, including with reference to FIG. 2, the error management portion 324 may support multiple types of error management information (e.g., a Reed-Solomon code, a cyclic redundancy check code, etc.), multiple types of management information (e.g., metadata), or both.

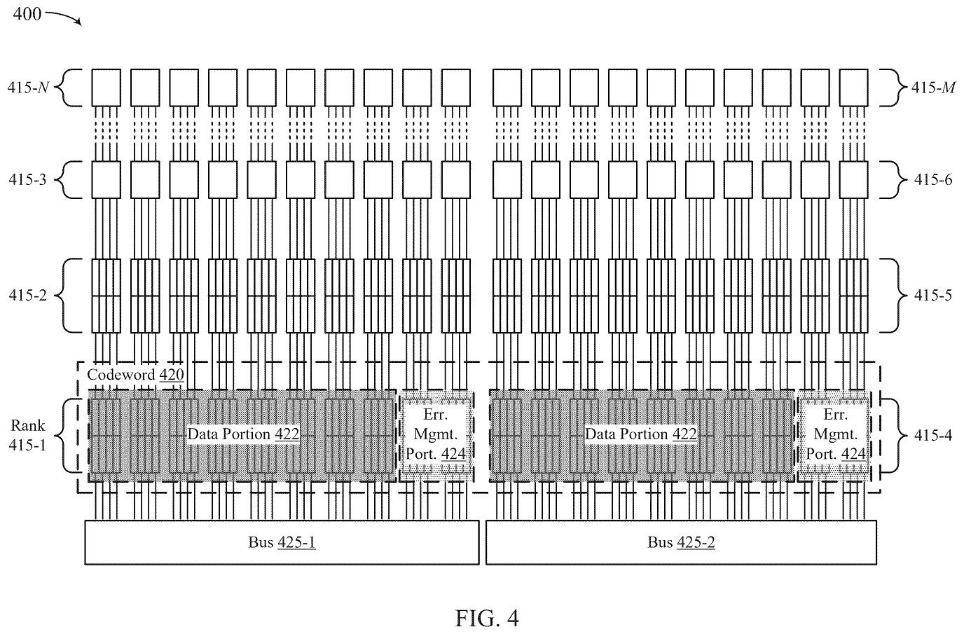

FIG. 4 shows an example of a subsystem that supports cross-memory rank error management in accordance with examples as disclosed herein.

The subsystem 400 may include the memory dies (which may be the same as or similar to the memory dies 200 of FIG. 2), the first bus 425-1 and the second bus 425-2, which may, respectively, be examples of, or configured similarly as, memory dies and buses described herein, including with reference to FIGS. 2 and 3.

In some examples, the first bus 425-1 is associated with a first channel for communicating data from a first set of memory dies and the second bus 425-2 is associated with a second channel for communicating data from a second set of memory dies. In some examples, data may be communicated over the first bus 425-1 and the second bus 425-2 simultaneously.

The ranks may be associated with different channels and buses—e.g., the first memory rank 415-1 through the Nth memory rank 415-N (e.g., memory ranks 415-1, 415-2, 415-3, through 415-N) may be associated with the first channel and the first bus 425-1, and the fourth memory rank 415-4 through the Mth memory rank 415-M (e.g., memory ranks 415-4, 415-5, 415-c, through 415-M) may be associated with the second channel and the second bus 425-2. In some examples, the fourth memory rank 415-4 may be referred to as the first memory rank of the second set of memory dies. For example, to distinguish the ranks of the first channel from the second channel, the following naming convention may be used: Memory Rank {channel}. {memory rank}. For example, the first memory rank 415-1 may be designated as Memory rank 1.1, the second memory rank 415-2 may be designated as Memory Rank 1.2, and so on. Also, the fourth memory rank 415-4 may be designated as Memory Rank 2.1, the fifth memory rank 415-5 may be designated as Memory Rank 2.2, and so on.

As described herein, to increase an error correcting capability of an error correction technique (e.g., a Reed-Solomon technique) within a memory rank without increasing an overprovisioning overhead in a memory system, a codeword (e.g., the codeword 420) may be stored across multiple ranks. In some examples, the codeword may be stored across ranks that are associated with different channels (e.g., the first memory rank 415-1 and the fourth memory rank 415-4). For example, a data portion 422 of the codeword 420 may be stored across a first set of memory dies in the first memory rank 415-1 and a first set of memory dies in the fourth memory rank 415-4. Also, an error management portion 424 of the codeword 420 may be stored across a second set of memory dies in the first memory rank 415-1 and a second set of memory dies in the fourth memory rank 415-4.

As such, error management information in the error management portion 424 may be used to correct symbols errors in the codeword 420 that occur in a part of the data portion 422 that is located within the first memory rank 415-1, in a part of the data portion 422 that is located within the fourth memory rank 415-4, or both. For example, for a Reed-Solomon code having the following values RS (28, 160, 128), the error management information may be used to correct up to sixteen (16) data symbols, (1280/8−128)÷2, that occur in the first memory rank 415-1, the fourth memory rank 415-4, or both. Accordingly, the error management information may be used to correct a failure of two memory dies within a single memory rank (e.g., the first memory rank 415-1, or the fourth memory rank 415-4).

In some examples, the codeword may be communicated with the memory system in two (e.g., parallel) BL16 commands, where the first BL16 command may access the data stored in a page of the first memory rank 415-1 and the second BL16 command may access the data stored in a page of the fourth memory rank 415-4.

As described herein, including with reference to FIG. 2, the error management portion 424 may support multiple types of error management information (e.g., a Reed-Solomon code, a cyclic redundancy check code, etc.), multiple types of management information (e.g., metadata), or both.

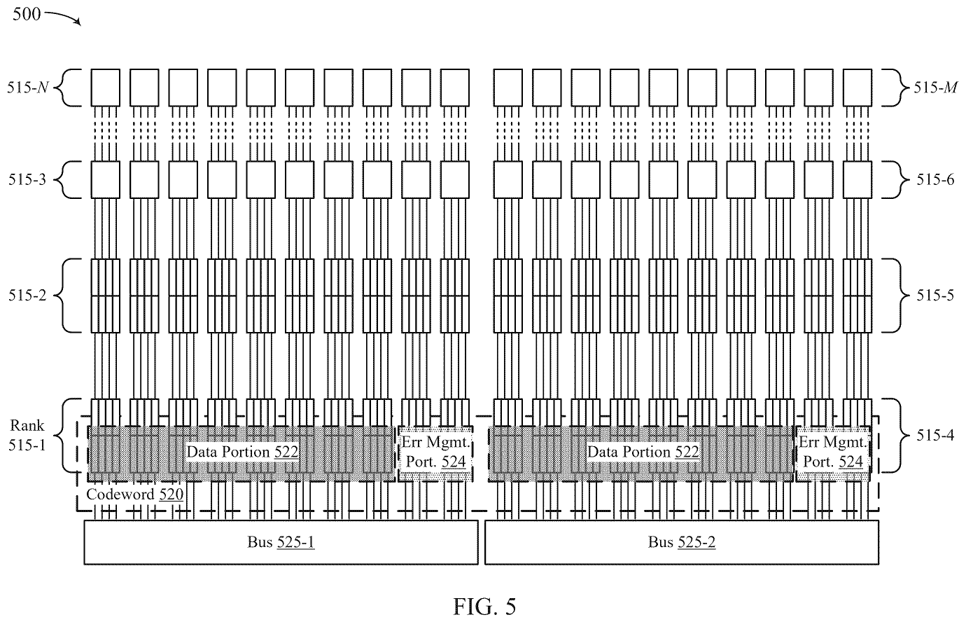

FIG. 5 shows an example of a subsystem that supports cross-memory rank error management in accordance with examples as disclosed herein.

The subsystem 500 may include the memory dies (which may be the same as or similar to the memory dies 200 of FIG. 2), the first bus 525-1, and the second bus 525-2, which may, respectively, be examples of, or configured similarly as, memory dies and buses described herein, including with reference to FIGS. 2 through 4.

As described herein, to increase an error correcting capability of an error correction technique (e.g., a Reed-Solomon technique) within a memory rank (e.g., memory ranks 515-1, 515-2, and 515-3 through 515-N, as well as memory ranks 515-4, 515-5, and 515-6 through 515-M) without increasing an overprovisioning overhead in a memory system, a codeword (e.g., the codeword 520) may be stored across multiple ranks. In some examples, the codeword may be stored across ranks that are associated with different channels (e.g., the first memory rank 515-1 and the fourth memory rank 515-4). For example, a data portion 522 of the codeword 520 may be stored across a first set of memory dies in the first memory rank 515-1 and a first set of memory dies in the fourth memory rank 515-4. Also, an error management portion 524 of the codeword 520 may be stored across a second set of memory dies in the first memory rank 515-1 and a second set of memory dies in the fourth memory rank 515-4.

In some examples, a first part of the data portion 522 is stored in a portion of a page of the first memory rank 515-1 and a second part of the data portion 522 is stored in a portion of a page of the fourth memory rank 515-4. Similarly, a first part of the error management portion 524 may be stored in the portion of the page of the first memory rank 515-1 and a second part of the error management portion 524 may be stored in a portion of a page of the fourth memory rank 515-4.

As such, error management information in the error management portion 524 may be used to correct symbols errors in the codeword 520 that occur in a part of the data portion 522 that is located within the first memory rank 515-1, in a part of the data portion 522 that is located within the fourth memory rank 515-4, or both. For example, for a Reed-Solomon code having the following values RS (28, 80, 64), the error management information may be used to correct up to eight (8) data symbols, (640/8−64)÷2, that occur in the first memory rank 515-1, the fourth memory rank 515-4, or both. Accordingly, the error management information may be used to correct a failure of two memory dies within a single memory rank (e.g., the first memory rank 515-1, or the fourth memory rank 515-4).

In some examples, the codeword may be communicated with the memory system in two (e.g., parallel) BC8 commands, where the first BC8 command may access the data stored in a page of the first memory rank 515-1 and the second BC8 command may access the data stored in a page of the fourth memory rank 515-4.

As described herein, including with reference to FIG. 2, the error management portion 524 may support multiple types of error management information (e.g., a Reed-Solomon code, a cyclic redundancy check code, etc.), multiple types of management information (e.g., metadata), or both.

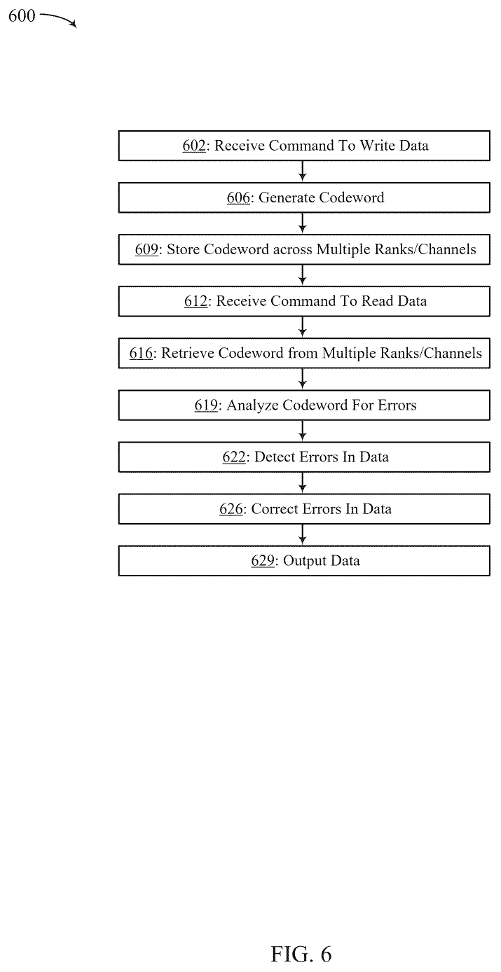

FIG. 6 shows an example of a set of operations for cross-memory rank error management in accordance with examples as disclosed herein.

The flowchart 600 may be performed by components of a memory system, as described herein, including with reference to FIGS. 2 through 5. In some examples, the flowchart 600 shows an example set of operations performed to support cross-memory rank error management. For example, the flowchart 600 may include operations for storing and retrieving codewords across ranks and/or channels of a memory system.

At 602, a write command for writing data to a memory system may be received (e.g., from a host system). The command may include data and an address associated with storing the data at the memory system. In some examples, the address is a logical address e.g., which may be associated with multiple physical addresses associated with different ranks, for example. In some examples, the command may include data and multiple addresses. In some examples, the multiple addresses are logical addresses that are associated with physical addresses associated with different ranks. In some examples, the multiple addresses are physical addresses associated with different ranks.

In some examples, the size of the data is based on a codeword size configured at the memory system. For example, if a configured codeword size is 640-bits, the size of the data may be 512 bits. Alternatively, if a configured codeword size is 320-bits, the size of the data may be 256-bits.

At 606, in response to the write command, a codeword may be generated at the memory system (e.g., based on the configured codeword size. As described herein, the codeword may include a data portion and an error management portion. In some examples, the error management portion may include error management information and metadata (or user data). In some examples, the error management portion may include multiple types of error management information (e.g., a Reed-Solomon code and a cyclic redundancy check code). In some examples, the error management portion may include first error management information (e.g., a Reed-Solomon code), second error management information (e.g., a cyclic redundancy check code), and metadata (or user data). In some examples, when the error management portion includes multiple types of information, the error correcting capabilities of the error management portion may be reduced such that the error management information may be capable of correcting at least a memory die failure but less than two memory die failures.

At 609, in response to the write command, the codeword may be stored across multiple ranks. In some examples, the ranks of the multiple ranks may be associated with respective channels. As described herein, a first part of the data portion may be stored in a first memory rank (at a first set of memory dies in the first memory rank) and a second part of the data portion may be stored in a second memory rank (at a first set of memory dies in the second memory rank). Also, a first part of the error management portion may be stored in the first memory rank (at a second set of memory dies in the first memory rank) and a second part of the error management portion may be stored in the second memory rank (at a second set of memory dies in the second memory rank).

At 612, a read command for reading data (e.g., the data previously stored in the memory system) from the memory system may be received (e.g., from a host system). The command may include one or more addresses (e.g., one or more logical or physical addresses) associated with the data.

At 616, in response to the read command, the codeword may be retrieved from the memory system. Retrieving the codeword may involve reading data from multiple ranks. In some examples, the ranks of the multiple ranks may be associated with respective channels. In some examples, the codeword is retrieved from the memory system using multiple BL16 commands, which may respectively be used to read a full page from a first memory rank storing a first portion of the codeword and a full page from a second memory rank storing a second portion of the codeword. In some examples, the codeword is retrieved from the memory system using multiple BC8 commands, which may respectively be used to read a portion (e.g., half) of a page from a first memory rank storing a first portion of the codeword and a portion of a page from a second memory rank storing a second portion of the codeword.

At 619, the retrieved codeword may be analyzed for errors—e.g., using the error management information stored in the error management portion of the retrieved codeword. In some examples, the processing load for analyzing the retrieved codeword may be reduced when BC8 commands are used (e.g., for smaller codewords) relative to when BL16 commands are used.

At 622, one or more errors may be detected in the retrieved codeword. In some examples, multiple errors associated with the failure of two memory dies may be detected in the retrieved codeword. As described herein, if the error management portion of the retrieved codeword is fully allocated to a Reed-Solomon code, the memory system may be capable of correcting the errors to recreate the originally stored data.

At 626, the one or more errors detected in the retrieved codeword may be corrected. In some examples, multiple errors corresponding to the failures of two dies within the two ranks used to store the codeword are corrected. In some examples, the two dies are located within one of the two ranks. As such, the data associated with the data portion of the codeword originally stored in the memory may be recreated.

At 629, the originally stored data associated with the data portion of the codeword may be output (e.g., to a host system).

Aspects of the flowchart 600 may be implemented by a controller, among other components. Additionally, or alternatively, aspects of the flowchart 600 may be implemented as instructions stored in memory (e.g., firmware stored in a memory coupled with a controller). For example, the instructions, when executed by a controller, may cause the controller to perform the operations of the flowchart 600.

One or more of the operations described in the flowchart 600 may be performed earlier or later, omitted, replaced, supplemented, or combined with another operation. Also, additional operations described herein may replace, supplement or be combined with one or more of the operations described in the flowchart 600.

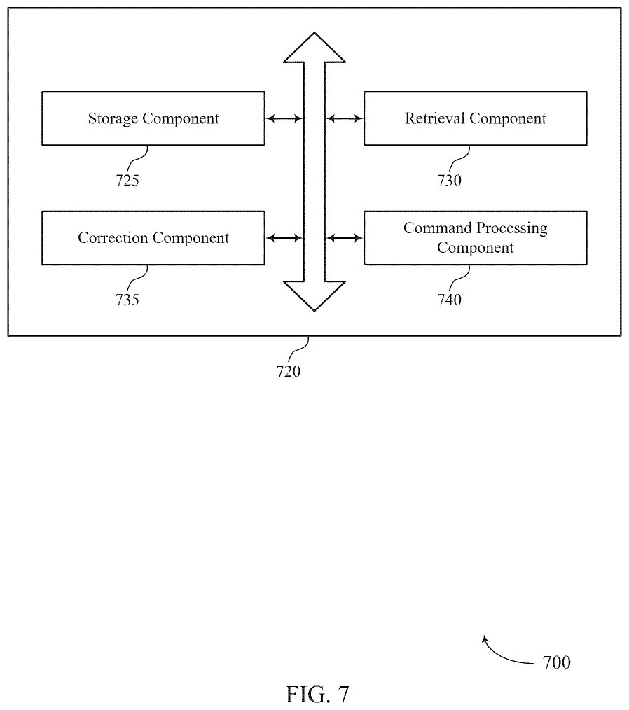

FIG. 7 shows a block diagram 700 of a memory system 720 that supports cross-memory rank error management in accordance with examples as disclosed herein. The memory system 720 may be an example of aspects of a memory system as described with reference to FIGS. 1 through 6. The memory system 720, or various components thereof, may be an example of means for performing various aspects of cross-memory rank error management as described herein. For example, the memory system 720 may include a storage component 725, a retrieval component 730, a correction component 735, a command processing component 740, or any combination thereof. Each of these components, or components of subcomponents thereof (e.g., one or more processors, one or more memories), may communicate, directly or indirectly, with one another (e.g., via one or more buses).

The storage component 725 may be configured as or otherwise support a means for storing a codeword at least partially in a first memory rank and at least partially in a second memory rank, where a data portion of the codeword is at least partially stored in the first memory rank and an error management portion of the codeword is at least partially stored in the second memory rank. The retrieval component 730 may be configured as or otherwise support a means for retrieving, after storing the codeword in the first memory rank and the second memory rank, the codeword from at least the first memory rank and the second memory rank. The correction component 735 may be configured as or otherwise support a means for correcting, based on retrieving the codeword, one or more errors in the data portion retrieved from the first memory rank using the error management portion retrieved from the second memory rank.

In some examples, correcting the data portion retrieved from the first memory rank includes correcting a plurality of errors in the data portion stored in the first memory rank resulting from a failure of two memory dies of the first memory rank.

In some examples, the first memory rank is accessible via a first data channel and the second memory rank is accessible via a second data channel.

In some examples, the first memory rank and the second memory rank are both accessible via a data channel.

In some examples, a second data portion of the codeword is stored in the second memory rank and a second error management portion of the codeword is stored in the first memory rank.

In some examples, retrieving the codeword includes retrieving, in response to a read command, a first portion of the codeword from the first memory rank using a burst length configured to access less than all the data stored at a physical memory address in the first memory rank, and retrieving, in response to the read command, a second portion of the codeword from the second memory rank using the burst length configured to access less than all the data stored at a second physical memory address in the second memory rank.

In some examples, a first set of memory dies of the first memory rank is configured to store data, a second set of memory dies of the first memory rank is configured to store error management information, data, or both, a first set of memory dies of the second memory rank is configured to store data, and a second set of memory dies of the second memory rank is configured to store error correction information, data, or both.

In some examples, the data portion of the codeword is stored in the first set of memory dies of the first memory rank, and the error management portion of the codeword is stored in the second set of memory dies of the second memory rank.

In some examples, a second data portion of the codeword is stored in the first set of memory dies of the second memory rank, and a second error management portion of the codeword is stored in the second set of memory dies of the first memory rank.

In some examples, the error management portion of the codeword includes a Reed-Solomon code, and the second error management portion of the codeword includes a cyclic redundancy check code.

In some examples, a metadata portion of the codeword is stored in the second set of memory dies of the first memory rank, the second set of memory dies of the second memory rank, or both.

In some examples, a metadata portion of the codeword is stored in the second set of memory dies of the first memory rank.

In some examples, the first memory rank is separately selectable from the second memory rank, the first set of memory dies of the first memory rank and the second set of memory dies of the first memory rank being simultaneously accessible using a first chip select, and the first set of memory dies of the second memory rank and the second set of memory dies of the second memory rank being simultaneously accessible using a second chip select.

In some examples, the storage component 725 may be configured as or otherwise support a means for storing a codeword at least partially in a first memory rank and at least partially in a second memory rank, where a first data portion of the codeword is stored in the first memory rank, a second data portion of the codeword is stored in the second memory rank, a first error management portion of the codeword is stored in the first memory rank, and a second error management portion of the codeword is stored in the second memory rank. In some examples, the retrieval component 730 may be configured as or otherwise support a means for retrieving, after storing the codeword in the first memory rank and the second memory rank, the codeword from at least the first memory rank and the second memory rank. In some examples, the correction component 735 may be configured as or otherwise support a means for correcting, based on retrieving the codeword, one or more errors in the first data portion retrieved from the first memory rank using the first error management portion retrieved from the first memory rank and the second error management portion stored in the second memory rank.

In some examples, the one or more errors in the first data portion includes a plurality of errors corresponding to a failure of two memory dies within the first memory rank.

In some examples, the one or more errors in the first data portion includes a plurality of errors corresponding to a failure of two memory dies within the second memory rank.

In some examples, the one or more errors in the first data portion includes a plurality of errors corresponding to a failure of a first memory die within the first memory rank and a second memory die within the second memory rank.

In some examples, the first memory rank is accessible via a first data channel and the second memory rank is accessible via a second data channel.

In some examples, the command processing component 740 may be configured as or otherwise support a means for receiving a command to store data at an address, where, in response to receiving the command, the codeword is stored at the address, the address being associated with first memory dies of the first memory rank and second memory dies of the second memory rank.

In some examples, the first memory rank is separately selectable from the second memory rank, a first set of memory dies of the first memory rank and a second set of memory dies of the first memory rank being simultaneously accessible using a first chip select, and a first set of memory dies of the second memory rank and a second set of memory dies of the second memory rank being simultaneously accessible using a second chip select.

In some examples, the described functionality of the memory system 720, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 720, or various components thereof, may be implemented at least in part by instructions (e.g., stored in memory, non-transitory computer-readable medium) executable by such at least one processor.

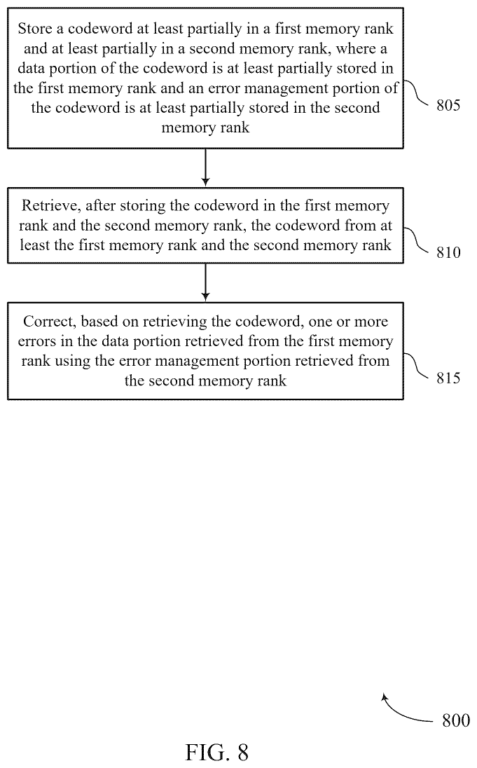

FIG. 8 shows a flowchart illustrating a method 800 that supports cross-memory rank error management in accordance with examples as disclosed herein. The operations of method 800 may be implemented by a memory system or its components as described herein. For example, the operations of method 800 may be performed by a memory system as described with reference to FIGS. 1 through 7. In some examples, a memory system may execute a set of instructions to control the functional elements of the device to perform the described functions. Additionally, or alternatively, the memory system may perform aspects of the described functions using special-purpose hardware.

At 805, the method may include storing a codeword at least partially in a first memory rank and at least partially in a second memory rank, where a data portion of the codeword is at least partially stored in the first memory rank and an error management portion of the codeword is at least partially stored in the second memory rank. In some examples, aspects of the operations of 805 may be performed by a storage component 725 as described with reference to FIG. 7.

At 810, the method may include retrieving, after storing the codeword in the first memory rank and the second memory rank, the codeword from at least the first memory rank and the second memory rank. In some examples, aspects of the operations of 810 may be performed by a retrieval component 730 as described with reference to FIG. 7.

At 815, the method may include correcting, based on retrieving the codeword, one or more errors in the data portion retrieved from the first memory rank using the error management portion retrieved from the second memory rank. In some examples, aspects of the operations of 815 may be performed by a correction component 735 as described with reference to FIG. 7.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for storing a codeword at least partially in a first memory rank and at least partially in a second memory rank, where a data portion of the codeword is at least partially stored in the first memory rank and an error management portion of the codeword is at least partially stored in the second memory rank; retrieving, after storing the codeword in the first memory rank and the second memory rank, the codeword from at least the first memory rank and the second memory rank; and correcting, based on retrieving the codeword, one or more errors in the data portion retrieved from the first memory rank using the error management portion retrieved from the second memory rank.
Aspect 2: The method, apparatus, or non-transitory computer-readable medium of aspect 1, where correcting the data portion retrieved from the first memory rank includes correcting a plurality of errors in the data portion stored in the first memory rank resulting from a failure of two memory dies of the first memory rank.
Aspect 3: The method, apparatus, or non-transitory computer-readable medium of any of aspects 1 through 2, where the first memory rank is accessible via a first data channel and the second memory rank is accessible via a second data channel.
Aspect 4: The method, apparatus, or non-transitory computer-readable medium of any of aspects 1 through 3, where the first memory rank and the second memory rank are both accessible via a data channel.
Aspect 5: The method, apparatus, or non-transitory computer-readable medium of any of aspects 1 through 4, where a second data portion of the codeword is stored in the second memory rank and a second error management portion of the codeword is stored in the first memory rank.
Aspect 6: The method, apparatus, or non-transitory computer-readable medium of any of aspects 1 through 5, where retrieving the codeword includes retrieving, in response to a read command, a first portion of the codeword from the first memory rank using a burst length configured to access less than all the data stored at a physical memory address in the first memory rank, and retrieving, in response to the read command, a second portion of the codeword from the second memory rank using the burst length configured to access less than all the data stored at a second physical memory address in the second memory rank.
Aspect 7: The method, apparatus, or non-transitory computer-readable medium of any of aspects 1 through 6, where a first set of memory dies of the first memory rank is configured to store data, a second set of memory dies of the first memory rank is configured to store error management information, data, or both, a first set of memory dies of the second memory rank is configured to store data, and a second set of memory dies of the second memory rank is configured to store error correction information, data, or both.
Aspect 8: The method, apparatus, or non-transitory computer-readable medium of aspect 7, where the data portion of the codeword is stored in the first set of memory dies of the first memory rank, and the error management portion of the codeword is stored in the second set of memory dies of the second memory rank.
Aspect 9: The method, apparatus, or non-transitory computer-readable medium of aspect 8, where a second data portion of the codeword is stored in the first set of memory dies of the second memory rank, and a second error management portion of the codeword is stored in the second set of memory dies of the first memory rank.
Aspect 10: The method, apparatus, or non-transitory computer-readable medium of aspect 9, where the error management portion of the codeword includes a Reed-Solomon code, and the second error management portion of the codeword includes a cyclic redundancy check code.
Aspect 11: The method, apparatus, or non-transitory computer-readable medium of any of aspects 9 through 10, where a metadata portion of the codeword is stored in the second set of memory dies of the first memory rank, the second set of memory dies of the second memory rank, or both.
Aspect 12: The method, apparatus, or non-transitory computer-readable medium of any of aspects 8 through 11, where a metadata portion of the codeword is stored in the second set of memory dies of the first memory rank.
Aspect 13: The method, apparatus, or non-transitory computer-readable medium of any of aspects 7 through 12, where the first memory rank is separately selectable from the second memory rank, the first set of memory dies of the first memory rank and the second set of memory dies of the first memory rank being simultaneously accessible using a first chip select, and the first set of memory dies of the second memory rank and the second set of memory dies of the second memory rank being simultaneously accessible using a second chip select.

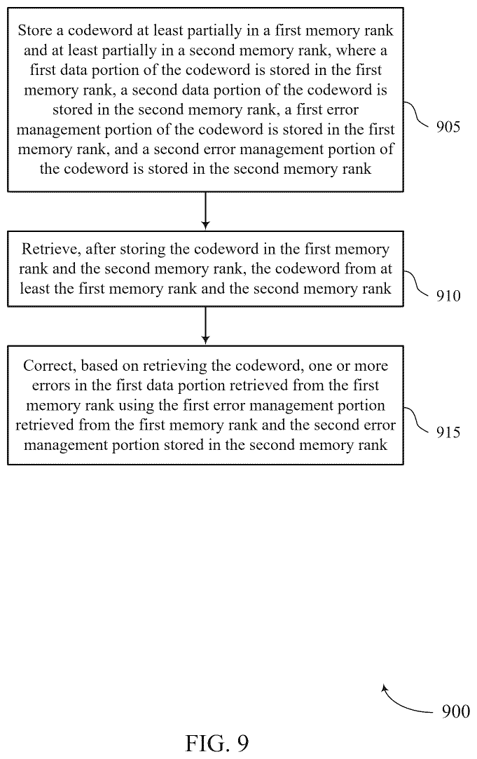

FIG. 9 shows a flowchart illustrating a method 900 that supports cross-memory rank error management in accordance with examples as disclosed herein. The operations of method 900 may be implemented by a memory system or its components as described herein. For example, the operations of method 900 may be performed by a memory system as described with reference to FIGS. 1 through 7. In some examples, a memory system may execute a set of instructions to control the functional elements of the device to perform the described functions. Additionally, or alternatively, the memory system may perform aspects of the described functions using special-purpose hardware.

At 905, the method may include storing a codeword at least partially in a first memory rank and at least partially in a second memory rank, where a first data portion of the codeword is stored in the first memory rank, a second data portion of the codeword is stored in the second memory rank, a first error management portion of the codeword is stored in the first memory rank, and a second error management portion of the codeword is stored in the second memory rank. In some examples, aspects of the operations of 905 may be performed by a storage component 725 as described with reference to FIG. 7.

At 910, the method may include retrieving, after storing the codeword in the first memory rank and the second memory rank, the codeword from at least the first memory rank and the second memory rank. In some examples, aspects of the operations of 910 may be performed by a retrieval component 730 as described with reference to FIG. 7.

At 915, the method may include correcting, based on retrieving the codeword, one or more errors in the first data portion retrieved from the first memory rank using the first error management portion retrieved from the first memory rank and the second error management portion stored in the second memory rank. In some examples, aspects of the operations of 915 may be performed by a correction component 735 as described with reference to FIG. 7.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:
Aspect 14: A method, apparatus, or non-transitory computer-readable medium including operations, features, circuitry, logic, means, or instructions, or any combination thereof for storing a codeword at least partially in a first memory rank and at least partially in a second memory rank, where a first data portion of the codeword is stored in the first memory rank, a second data portion of the codeword is stored in the second memory rank, a first error management portion of the codeword is stored in the first memory rank, and a second error management portion of the codeword is stored in the second memory rank; retrieving, after storing the codeword in the first memory rank and the second memory rank, the codeword from at least the first memory rank and the second memory rank; and correcting, based on retrieving the codeword, one or more errors in the first data portion retrieved from the first memory rank using the first error management portion retrieved from the first memory rank and the second error management portion stored in the second memory rank.
Aspect 15: The method, apparatus, or non-transitory computer-readable medium of aspect 14, where the one or more errors in the first data portion includes a plurality of errors corresponding to a failure of two memory dies within the first memory rank.
Aspect 16: The method, apparatus, or non-transitory computer-readable medium of any of aspects 14 through 15, where the one or more errors in the first data portion includes a plurality of errors corresponding to a failure of two memory dies within the second memory rank.
Aspect 17: The method, apparatus, or non-transitory computer-readable medium of any of aspects 14 through 16, where the one or more errors in the first data portion includes a plurality of errors corresponding to a failure of a first memory die within the first memory rank and a second memory die within the second memory rank.
Aspect 18: The method, apparatus, or non-transitory computer-readable medium of any of aspects 14 through 17, where the first memory rank is accessible via a first data channel and the second memory rank is accessible via a second data channel.
Aspect 19: The method, apparatus, or non-transitory computer-readable medium of any of aspects 14 through 18, further including operations, features, circuitry, logic, means, or instructions, or any combination thereof for receiving a command to store data at an address, where, in response to receiving the command, the codeword is stored at the address, the address being associated with first memory dies of the first memory rank and second memory dies of the second memory rank.
Aspect 20: The method, apparatus, or non-transitory computer-readable medium of any of aspects 14 through 19, where the first memory rank is separately selectable from the second memory rank, a first set of memory dies of the first memory rank and a second set of memory dies of the first memory rank being simultaneously accessible using a first chip select, and a first set of memory dies of the second memory rank and a second set of memory dies of the second memory rank being simultaneously accessible using a second chip select.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a first memory rank;
a second memory rank; and
processing circuitry coupled with the first memory rank and the second memory rank, wherein the processing circuitry is configured to cause the memory system to:
store a codeword at least partially in the first memory rank and at least partially in the second memory rank, wherein a data portion of the codeword is at least partially stored in the first memory rank and an error management portion of the codeword is at least partially stored in the second memory rank;
retrieve, after storing the codeword in the first memory rank and the second memory rank, the codeword from at least the first memory rank and the second memory rank; and
correct, based on retrieving the codeword, one or more errors in the data portion of the codeword retrieved from the first memory rank using the error management portion of the codeword retrieved from the second memory rank.

2. The memory system of claim 1, wherein, to correct the data portion retrieved from the first memory rank, the processing circuitry is configured to cause the memory system to:
correct a plurality of errors in the data portion stored in the first memory rank resulting from a failure of two memory dies of the first memory rank.

3. The memory system of claim 1, further comprising:
a first data channel; and
a second data channel, wherein the first memory rank is accessible via the first data channel and the second memory rank is accessible via the second data channel.

4. The memory system of claim 1, further comprising:
a data channel, wherein the first memory rank and the second memory rank are both accessible via the data channel.

5. The memory system of claim 1, wherein a second data portion of the codeword is stored in the second memory rank and a second error management portion of the codeword is stored in the first memory rank.

6. The memory system of claim 1, wherein, to retrieve the codeword, the processing circuitry is configured to cause the memory system to:
retrieve, in response to a read command, a first portion of the codeword from the first memory rank using a burst length configured to access less than all the data stored at a physical memory address in the first memory rank, and
retrieve, in response to the read command, a second portion of the codeword from the second memory rank using the burst length configured to access less than all the data stored at a second physical memory address in the second memory rank.

7. The memory system of claim 1, wherein:
a first set of memory dies of the first memory rank is configured to store data,
a second set of memory dies of the first memory rank is configured to store error management information, data, or both,
a first set of memory dies of the second memory rank is configured to store data, and
a second set of memory dies of the second memory rank is configured to store error correction information, data, or both.

8. The memory system of claim 7, wherein:
the data portion of the codeword is stored in the first set of memory dies of the first memory rank, and
the error management portion of the codeword is stored in the second set of memory dies of the second memory rank.

9. The memory system of claim 8, wherein:
a second data portion of the codeword is stored in the first set of memory dies of the second memory rank, and
a second error management portion of the codeword is stored in the second set of memory dies of the first memory rank.

10. The memory system of claim 9, wherein:
the error management portion of the codeword comprises a Reed-Solomon code, and
the second error management portion of the codeword comprises a cyclic redundancy check code.

11. The memory system of claim 9, wherein a metadata portion of the codeword is stored in the second set of memory dies of the first memory rank, the second set of memory dies of the second memory rank, or both.

12. The memory system of claim 8, wherein a metadata portion of the codeword is stored in the second set of memory dies of the first memory rank.

13. The memory system of claim 7, wherein the first memory rank is separately selectable from the second memory rank, the first set of memory dies of the first memory rank and the second set of memory dies of the first memory rank being simultaneously accessible using a first chip select, and the first set of memory dies of the second memory rank and the second set of memory dies of the second memory rank being simultaneously accessible using a second chip select.

14. A memory system, comprising:
a first memory rank;
a second memory rank; and
processing circuitry coupled with the first memory rank and the second memory rank, wherein the processing circuitry is configured to cause the memory system to:
store a codeword at least partially in the first memory rank and at least partially in the second memory rank, wherein a first data portion of the codeword is stored in the first memory rank, a second data portion of the codeword is stored in the second memory rank, a first error management portion of the codeword is stored in the first memory rank, and a second error management portion of the codeword is stored in the second memory rank;
retrieve, after storing the codeword in the first memory rank and the second memory rank, the codeword from at least the first memory rank and the second memory rank; and
correct, based on retrieving the codeword, one or more errors in the first data portion retrieved from the first memory rank using the first error management portion retrieved from the first memory rank and the second error management portion retrieved from the second memory rank.

15. The memory system of claim 14, wherein the one or more errors in the first data portion comprises a plurality of errors corresponding to a failure of two memory dies within the first memory rank.

16. The memory system of claim 14, wherein the one or more errors in the first data portion comprises a plurality of errors corresponding to a failure of two memory dies within the second memory rank.

17. The memory system of claim 14, wherein the one or more errors in the first data portion comprises a plurality of errors corresponding to a failure of a first memory die within the first memory rank and a second memory die within the second memory rank.

18. The memory system of claim 14, further comprising:
a first data channel; and
a second data channel, wherein the first memory rank is accessible via the first data channel and the second memory rank is accessible via the second data channel.

19. The memory system of claim 14, wherein the processing circuitry is further configured to cause the memory system to:
receive a command to store data at an address, wherein, in response to receiving the command, the codeword is stored at the address, the address being associated with first memory dies of the first memory rank and second memory dies of the second memory rank.

20. The memory system of claim 14, wherein the first memory rank is separately selectable from the second memory rank, a first set of memory dies of the first memory rank and a second set of memory dies of the first memory rank being simultaneously accessible using a first chip select, and a first set of memory dies of the second memory rank and a second set of memory dies of the second memory rank being simultaneously accessible using a second chip select.

21. A method, comprising:
storing a codeword at least partially in a first memory rank and at least partially in a second memory rank, wherein a data portion of the codeword is at least partially stored in the first memory rank and an error management portion of the codeword is at least partially stored in the second memory rank;
retrieving, after storing the codeword in the first memory rank and the second memory rank, the codeword from at least the first memory rank and the second memory rank; and
correcting, based on retrieving the codeword, one or more errors in the data portion retrieved from the first memory rank using the error management portion retrieved from the second memory rank.

22. The method of claim 21, wherein correcting the data portion retrieved from the first memory rank comprises:
correcting a plurality of errors in the data portion stored in the first memory rank resulting from a failure of two memory dies of the first memory rank.

23. The method of claim 21, wherein the first memory rank is accessible via a first data channel and the second memory rank is accessible via a second data channel.

24. The method of claim 21, wherein a second data portion of the codeword is stored in the second memory rank and a second error management portion of the codeword is stored in the first memory rank.

25. A method, comprising:
storing a codeword at least partially in a first memory rank and at least partially in a second memory rank, wherein a first data portion of the codeword is stored in the first memory rank, a second data portion of the codeword is stored in the second memory rank, a first error management portion of the codeword is stored in the first memory rank, and a second error management portion of the codeword is stored in the second memory rank;
retrieving, after storing the codeword in the first memory rank and the second memory rank, the codeword from at least the first memory rank and the second memory rank; and
correcting, based on retrieving the codeword, one or more errors in the first data portion retrieved from the first memory rank using the first error management portion retrieved from the first memory rank and the second error management portion stored in the second memory rank.

26. The method of claim 25, wherein the one or more errors in the first data portion comprises a plurality of errors corresponding to a failure of two memory dies within the first memory rank.

27. The method of claim 25, further comprising:
receiving a command to store data at an address, wherein, in response to receiving the command, the codeword is stored at the address, the address being associated with first memory dies of the first memory rank and second memory dies of the second memory rank.

28. A non-transitory, computer-readable medium storing code comprising instructions executable by processing circuitry of a memory system to cause the memory system to:
storing a codeword at least partially in a first memory rank and at least partially in a second memory rank, wherein a data portion of the codeword is at least partially stored in the first memory rank and an error management portion of the codeword is at least partially stored in the second memory rank;
retrieving, after storing the codeword in the first memory rank and the second memory rank, the codeword from at least the first memory rank and the second memory rank; and
correcting, based on retrieving the codeword, one or more errors in the data portion retrieved from the first memory rank using the error management portion retrieved from the second memory rank.

29. The non-transitory, computer-readable medium of claim 28, wherein, to correct the data portion retrieved from the first memory rank, the instructions are executable by the processing circuitry to:
correct a plurality of errors in the data portion stored in the first memory rank resulting from a failure of two memory dies of the first memory rank.

30. The non-transitory, computer-readable medium of claim 28, wherein the first memory rank is accessible via a first channel and the second memory rank is accessible via a second channel.
